(19) United States
(12) Patent Application Publication
(10) Pub. No.: US 2026/0322351 A1
(43) Pub. Date: Oct. 15, 2026

(54) DEVICE, ELECTRICAL DEVICE, SUBSTRATE, AND METHOD FOR MANUFACTURING DEVICE

(71) Applicant: KYOCERA CORPORTION, Kyoto (JP)

(72) Inventors: Kazutaka MAEDA, Kyoto (JP); Daisuke TOYOTA, Kyoto (JP); Suguru MISAWA, Kyoto (JP)

(73) Assignee: KYOCERA CORPORTION, Kyoto (JP)

(21) Appl. No.: 19/485,698

(22) PCT Filed: Jan. 22, 2024
(86) PCT No.: PCT/JP2024/001574

§ 371 Date: Nov. 19, 2025

(30) Foreign Application Priority Data
May 25, 2023 (JP) 2023-086298

(51) Int. Cl. H03H 9/05; H03H 3/08; H03H 9/25

(52) U.S. Cl. CPC H03H 9/059; H03H 3/08; H03H 9/25

(57) ABSTRACT

To secure a sufficient interfacial strength in a solder bonding portion even after a high-temperature process such as reflow bonding. The device includes a base including a first surface, an electrode located on the first surface of the base, and a bonding portion located on the electrode. The bonding portion includes a first layer, a second layer, and a third layer in order from the electrode side. The first layer includes Mo as a main component. The second layer includes β-Sn as a main component. The third layer includes solder.

### TECHNICAL FIELD

The present disclosure relates to a device, an electrical device, a substrate, and a method for manufacturing the device.

### BACKGROUND OF INVENTION

A device equipped with an electronic component is mounted on a mounting substrate of an electrical device by solder.

For example, an elastic wave device disclosed in Patent Document 1 includes a pad (electrode) provided on a piezoelectric substrate and an under-bump metal provided on the pad to facilitate bonding with solder.

### CITATION LIST

### Patent Literature

Patent Document 1: Japanese International Publication WO 2015/022931

### SUMMARY

A device according to an aspect of the present disclosure includes: a base including a first surface; an electrode located on the first surface of the base; and a bonding portion located on the electrode, wherein the bonding portion includes a first layer, a second layer, and a third layer in order from a side of the electrode, the first layer includes Mo as a main component, the second layer includes β-Sn as a main component, and the third layer includes solder.

An electrical device according to an aspect of the present disclosure includes the above device.

A substrate according to an aspect of the present disclosure includes: a base including a first surface; an electrode located on the first surface of the base; a barrier layer located on the electrode; and a bonding layer located on the barrier layer, wherein the barrier layer includes Mo as a main component, and the bonding layer includes at least one of Ni, Ag, Au, and Cu.

A method for manufacturing a device according to an aspect of the present disclosure includes: preparing the substrate, and placing solder on the bonding layer and heating the solder to produce a bonding portion on the electrode, wherein the bonding portion includes a first layer, a second layer, and a third layer in order from a side of the electrode, the first layer includes Mo as a main component, the second layer includes β-Sn as a main component, and the third layer includes solder.

### BRIEF DESCRIPTION OF THE DRAWINGS

FIG. 1 is a cross-sectional structural view illustrating a part of a substrate according to a first embodiment of the present disclosure.

FIG. 2 is a cross-sectional structural view illustrating a part of a device according to the first embodiment of the present disclosure.

FIG. 3 is a micrograph of a cross-section of an electrode and a bonding portion according to the first embodiment of a present disclosure.

FIG. 4 is a micrograph of a cross section of an electrode and a bonding portion according to the first embodiment of the present disclosure, illustrating a further enlarged view of the vicinity of a second layer.

FIG. 5 is a diagram schematically illustrating an arrangement of atoms in a [111] direction of β-Sn and an arrangement of atoms in a [121] direction of Mo in the bonding portion according to the first embodiment of the present disclosure.

FIG. 6 is a cross-sectional structural view illustrating a part of an electronic module including the device according to the first embodiment of the present disclosure.

FIG. 7 is a cross-sectional structural view of an acoustic wave device according to a second embodiment of the present disclosure.

FIG. 8 is a micrograph of a bonding portion of an electronic module of the present disclosure.

FIG. 9 is a graph of the results of evaluating the bonding strength of a comparative example in a second demonstration test.

FIG. 10 is a graph of the results of evaluating the bonding strength of a comparative example in the second demonstration test.

FIG. 11 is a graph of the results of evaluating the bonding strength of a comparative example in the second demonstration test.

FIG. 12 is a graph of the results of evaluating the bonding strength of an example in the second demonstration test.

FIG. 13 is a graph of the results of evaluating the bonding strength of examples and a comparative example in a third demonstration test.

FIG. 14 is a graph of the results of evaluating the bonding strength of examples in a fourth demonstration test.

FIG. 15 is a graph of the results of evaluating the bonding strength of an example in a fifth demonstration test.

FIG. 16 is a graph of the results of evaluating the bonding strength of an example in a sixth demonstration test.

FIG. 17 is a graph showing the results of nanoindentation in an eighth demonstration test.

FIG. 18 is a Weibull plot in a ninth demonstration test.

FIG. 19 is a schematic view of an electrode structure produced in an additional test.

FIG. 20 is a diagram illustrating an overview of a steel ball drop test.

FIG. 21 is a graph showing the results of the steel ball drop test.

FIG. 22 illustrates SEM observation results after a drop test of a comparative example.

FIG. 23 illustrates SEM observation results after a drop test of an example.

FIG. 24 illustrates the results of energy dispersive X-ray analysis (EDX) of a breakage surface of an electrode of an example on a Mo electrode side.

### DESCRIPTION OF EMBODIMENTS

In the elastic wave device disclosed in Patent Document 1, when a high-temperature process such as reflow bonding is repeatedly performed or when the device is used at a high temperature for a long time, various metal materials included in the under-bump metal and the like react with the metal included in the solder. This may deteriorate the mechanical properties of the solder and reduce the interfacial strength of a solder bonding portion.

According to an aspect of the present disclosure, a sufficient interfacial strength can be secured in a solder bonding portion even after a high-temperature process such as reflow bonding.

### First Embodiment

An embodiment of the present disclosure is described below in detail. In the following description, a device according to the present disclosure may be, for example, an electronic device including a substrate and an electronic component such as an electronic element mounted on the substrate. An electronic module (electrical device) including the device is configured by mounting the device on a mounting substrate (module substrate).

### Substrate

An exemplary substrate 110 according to the present disclosure is described below.

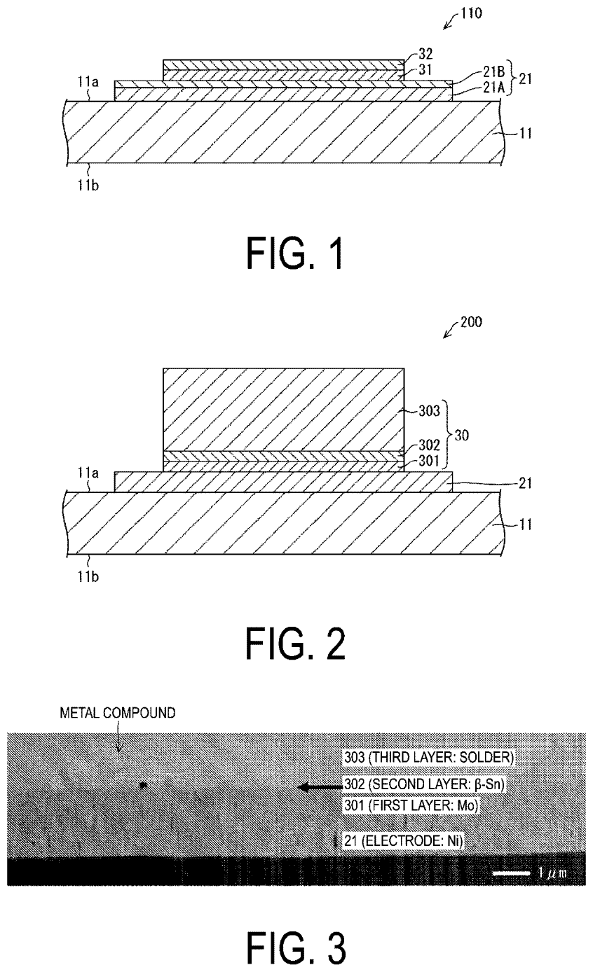

FIG. 1 is a cross-sectional structural view illustrating a part of the substrate 110 according to the first embodiment of the present disclosure. FIG. 1 is an enlarged cross-sectional structural view of a portion of the substrate 110 where an electrode 21 is located.

The substrate 110 includes a base 11, the electrode 21, a barrier layer 31, and a bonding layer 32. In the substrate 110, the barrier layer 31 and the bonding layer 32 are layered in this order from the electrode 21 side.

The substrate 110 is a substrate on which electronic components are mounted, and may include internal wirings located inside the substrate 110 and through conductors that vertically connect the internal wirings to each other.

The base 11 included in the substrate 110 may be formed of a single layer or a plurality of layers. The base 11 may include a first surface 11a and a second surface 11b located on an opposite side of the first surface 11a. Electronic components such as electronic elements may be mounted on the first surface 11a or the second surface 11b.

The base 11 may have an insulation property. In this case, the base 11 may be made of, for example, a ceramic such as an aluminum nitride-based sintered body, an aluminum oxide-based sintered body (alumina ceramic), a silicon nitride-based sintered body, a mullite-based sintered body, or a glass ceramic sintered body. Alternatively, the base 11 may be made of a resin such as an epoxy resin, a polyimide resin, an acrylic resin, a phenol resin, and a fluorine-based resin. Examples of the fluorine-based resin include a polyester resin and a tetrafluoroethylene resin. Alternatively, the base 11 may be a Si substrate. Alternatively, the base 11 may be formed by a combination of a support substrate made of Si and a piezoelectric substrate made of a single crystal material of lithium tantalate (LiTaO₃: also referred to as LT) or lithium niobate (LiNbO₃: also referred to as LN).

### Electrode

The electrode 21 included in the substrate 110 electrically connects the device 200 including the substrate 110 to a circuit board. The electrode 21 is located on the first surface 11a of the base 11. The substrate 110 may include a plurality of electrodes 21 on the first surface 11a.

The electrode 21 may include a wiring layer 21A for communicating signals and an adhesion layer 21B for increasing the adhesion between the wiring layer 21A and the barrier layer 31.

The wiring layer 21A may include, for example, at least one of a Ni layer containing Ni (nickel) as a main component, a Cu layer containing Cu (copper) as a main component, a layer made of an alloy containing Ni (nickel) and Cu (copper), an Al layer containing Al (aluminum) as a main component, and a Ti layer containing Ti (titanium) as a main component.

The adhesion layer 21B may include at least one of a layer containing Ti as a main component and a layer containing Cr as a main component. The adhesion layer 21B includes at least one of the layer containing Ti as a main component and the layer containing Cr as a main component, so that the adhesion between the wiring layer 21A and the barrier layer 31 can be improved. The adhesion layer 21B may be made only of the layer containing Ti as a main component.

The adhesion layer 21B may be in contact with the barrier layer 31. As described in detail in the section of <Configuration of Device> below, the barrier layer 31 is referred to as a first layer 301 in a device 200 (see FIG. 2). Therefore, in the device 200, the adhesion layer 21B may be in contact with the first layer 301. An electrode structure has a layered structure including a wiring layer, an adhesion layer, and a protective layer that protects the electrode and acts as a base of the barrier layer. The protective layer can be formed of, for example, a single Ni layer or a multilayer of a Ni layer and an Au layer. By using the barrier layer as the barrier layer 31 containing Mo as a main component according to the present disclosure, the electrode 21 according to the present disclosure may have no protective layer. The configuration in which the adhesion layer 21B is in contact with the barrier layer 31 can reduce the cost of the electrode 21 and make the electrode 21 thinner.

The substrate 110 may have a metallized layer on the surface of the base 11, separately from the electrode 21. The metallized layer includes, for example, a metallized layer that is provided in a mounting region of the base 11 where an electronic component is mounted and that can be electrically connected to the electronic component.

When the base 11 is made of an electrically insulating ceramic, the metallized layer may be made of, for example, any one of tungsten (W), molybdenum (Mo), manganese (Mn), silver (Ag), Ni, and Cu, or an alloy containing at least one of these metals. When the base 11 is made of a resin, the metallized layer may be made of, for example, any one of Cu, gold (Au), aluminum (Al), Ni, Mo, and Ti, or an alloy containing at least one of these metals. The internal wiring and the through conductor may also have the same configuration as that of to the metallization layer.

### Barrier Layer

The barrier layer 31 is a layer containing Mo as a main component. The manufacturing process of the device and the electronic module including the substrate 110 includes a solder bonding process being a high-temperature process. For example, when solder balls are placed and then heated, the molten high-temperature solder is applied onto the electrode 21. When reflow bonding is further performed, the device 200 or an electronic module 300 with the electrode portion coated with solder is heated in a reflow furnace. In addition, the solder bonding portion may be repeatedly or continuously exposed to a high-temperature state due to heat or the like generated when the electronic module 300 is used. In such a case, when the barrier layer 31 is not provided, the electrode metal such as Cu and Ni contained in the electrode 21 is dissolved and reacts with a metal such as tin (Sn) and Cu contained in the solder, thereby forming a metal compound. The metal compound is hard and brittle, and thus is likely to be a starting point of a crack.

The barrier layer 31 is located between the electrode 21 and the solder, so that the possibility of a reaction between the electrode metal included in the electrode 21 and the metal included in the solder can be reduced. In other words, the diffusion of the electrode metal into the solder can be reduced. This makes it possible to reduce the formation of the metal compound. A thickness of the barrier layer 31 may be, for example, 0.1 μm or more. When the barrier layer 31 has a thickness of 0.1 μm or more, the possibility of a reaction between the electrode metal and the metal of the solder layer can be significantly reduced. This makes it possible to maintain interfacial strength.

Although FIG. 1 illustrates an example in which the barrier layer 31 covers a part of the electrode 21, the barrier layer 31 may cover the entire exposed surface of the electrode 21.

Bonding layer
The bonding layer 32 is a layer that is located on the barrier layer 31 and contains at least one of Ni, Ag, Au, and Cu. The presence of the bonding layer 32 secures the wettability of the solder, so that the interfacial strength of a solder interface can be improved.

The bonding layer 32 may include a base layer located on the barrier layer 31 and a surface layer located on the base layer.

For example, the bonding layer 32 may have a layered structure including a Ni layer located on the barrier layer 31 as a base layer and an Au layer located on the base layer. With such a configuration, the wettability is significantly improved compared to the case where a single Au layer is used as the bonding layer 32, for example.

Alternatively, the bonding layer 32 may include a layer made of a silver alloy containing Ag as a main component. For example, the bonding layer 32 may have a layered structure including a Ni layer located on the barrier layer 31 as a base layer and a layer made of a silver alloy located on the base layer. The silver alloy may be an alloy containing Ag as a main component, and may be, for example, APC commercially available from Furuya Metal Co., Ltd. With such a configuration, the cost can be reduced compared with the case where an Au layer is used as the outermost layer of the bonding layer 32. In addition, by using a layer made of a silver alloy as the outermost layer of the bonding layer 32, the wettability is further improved compared with the case where an Au layer is used. In addition, since the layer made of a silver alloy is slowly dissolved in the solder when the layer is brought into contact with a molten solder, the dissolution of the electrode metal can be further reduced particularly in the case where the solder bonding is repeated.

The thickness of the bonding layer 32 may be smaller than the thickness of the electrode 21. For example, the thickness of the bonding layer 32 may be from 0.1 μm to 1 μm, or may be 0.1μm.

In a high-temperature state such as solder bonding, the metal contained in the bonding layer 32 and the metal contained in the solder may react with each other to form a metal compound. By setting the thickness of the bonding layer 32 to the above-described thickness, the amount of metal eluted from the bonding layer 32 at the time of solder bonding or the like can be reduced, and the amount of the metal compound formed can be reduced. In addition, since the amount of metal eluted from the sufficiently thin bonding layer 32 is small, coarse particles of the metal compound are less likely to be formed, and the bonding layer 32 is less likely to be brittle. That is, the bonding portion 30 having excellent interfacial strength can be implemented while securing the wettability of the solder. The bonding portion 30 is described below.

### Configuration of Device

A configuration of the device 200 as an exemplary device according to the present disclosure is described below. FIG. 2 is a cross-sectional structural view illustrating a part of the device 200 according to the first embodiment of the present disclosure. FIG. 2 is an enlarged cross-sectional structural view of the electrode 21 included in the device 200, and illustrates no electronic components and the like included in the device 200.

The device 200 according to the present disclosure is obtained by, for example, placing solder balls on the substrate 110 illustrated in FIG. 1 and then heating the solder balls. More specifically, a method for manufacturing the device 200 includes (1) preparing the substrate 110, and (2) placing solder on the bonding layer 32 of the substrate 110 and heating the solder to produce the bonding portion 30 on the electrode 21. Hereinafter, for the sake of simplicity, the step (1) is referred to as a substrate preparation step and the step (2) is referred to as a bonding portion production step.

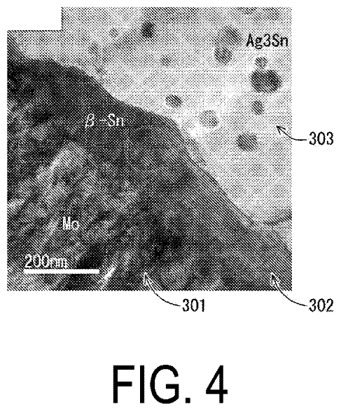

The device 200 includes the base 11, the electrode 21, and the bonding portion 30. The bonding portion 30 is located on the electrode 21, and includes a first layer 301, a second layer 302, and a third layer 303 in order from the electrode 21 side. FIG. 3 is a scanning transmission electron microscopy (STEM) photograph of a cross section of the electrode 21 and the bonding portion 30. FIG. 4 is a STEM photograph of a cross section of the electrode 21 and the bonding portion 30, illustrating a further enlarged view of the vicinity of the second layer 302. The cross-sectional photographs of FIGS. 3 and 4 were obtained by cutting out a portion including the electrode 21 and the bonding portion 30 of the device 200 by a focused ion beam (FIB) method and photographing the portion by STEM.

The first layer 301 is a layer containing Mo as a main component. The first layer 301 in the device 200 corresponds to the barrier layer 31 of the substrate 110. The barrier layer 31 is hardly changed even when heating after the solder ball is placed and further reflow bonding are repeated, and is located in the bonding portion 30 as the first layer 301.

The second layer 302 is a layer containing β-Sn as a main component. The second layer 302 is formed when the substrate 110 according to the present disclosure is solder-bonded. For example, the second layer 302 in the device 200 is formed in the above bonding portion production step.

In the bonding portion production step, when the solder is placed on the bonding layer 32 and heated, at least a part of the metal of the bonding layer 32 reacts with the metal contained in the molten solder to form one or more metal compounds. The metal compound may be a Sn compound. For example, when the bonding layer 32 before solder bonding contains Ni as a main component, a compound containing at least one of Ni₃Sn₄, Ni₃Sn₂, Ni₃Sn, (Cu, Ni)₃Sn₄, and (Cu, Ni)₆Sn₅ can be formed. The metal compound can be formed as a compound lump in the third layer 303 in the vicinity of the second layer 302 (referring to FIG. 3). That is, the third layer 303 may contain a metal compound formed by a reaction between the metal contained in the bonding layer 32 and the metal contained in the solder.

By the heating, at least a part of the bonding layer 32 is taken into the third layer 303 to form a metal compound, and the second layer 302 is formed between the third layer 303 and the first layer 301. It is considered that the second layer 302 is formed by the growth of the oriented β-Sn crystal in the vicinity of the first layer 301 when the solder that becomes the third layer 303 is melted. The growth of the β-Sn crystal is caused by the fact that the first layer 301 is a layer containing Mo as a main component. For example, the inventors have confirmed that a layer containing β-Sn as a main component is not formed when tungsten is used as the barrier layer.

The second layer 302 may be located on the entire surface between the first layer 301 and the third layer 303. Alternatively, a region where the second layer 302 is not present between the first layer 301 and the third layer 303 may be partially present. A part of the bonding layer 32 of the substrate 110 may remain between the first layer 301 and the third layer 303.

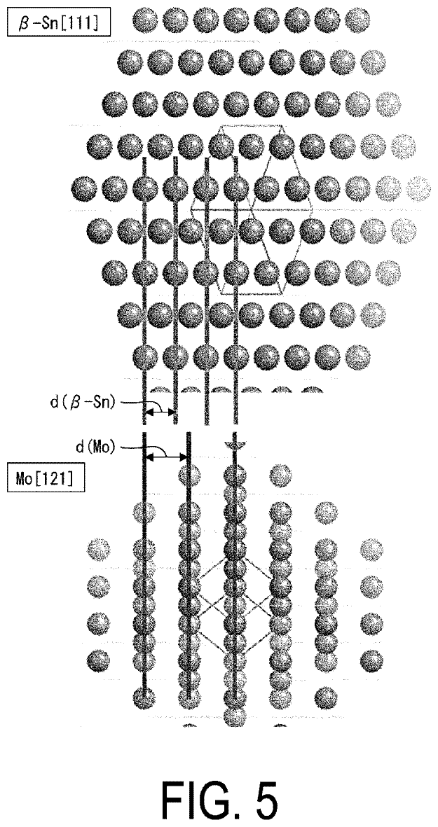

A lattice structure of the first layer 301 and the second layer 302 is described below. In the bonding portion 30, a {111} plane of Mo contained in the first layer 301 and a {110} plane of β-Sn contained in the second layer 302 may be substantially parallel to each other. The term “substantially parallel” means that the planes are not required to be strictly parallel to each other, and for example, an inclination of ±5° of one plane with respect to the other plane is allowable. FIG. 5 is a diagram schematically illustrating an arrangement of atoms in the [111] direction of β-Sn and an arrangement of atoms in the [121] direction of Mo. The interatomic distance d(β-Sn) in the {112} plane of β-Sn is 1.4843 Å, and the interatomic distance d(Mo) in the {110} plane of Mo is 2.2254 Å. The lengths of three interatomic distances of β-Sn and two interatomic distances of Mo are 4.4529 Å (=3×d(β-Sn)) and 4.4508 (=2×d(Mo)), which are almost equal to each other.

The interfacial strength between the first layer 301 and the second layer 302 can be maintained by the characteristic matching of the interatomic distances of the two layers as described above, which is caused by the {111} plane of Mo and the {110} plane of β-Sn being substantially parallel to each other.

Many of metal compounds generated near the solder bonding surface by the reaction between the electrode metal and the solder are hard and brittle, but β-Sn, which is the main component of the second layer 302, is softer than the metal compounds. The device 200 according to the present disclosure can significantly improve the impact resistance by having the second layer 302 on the solder bonding surface. This makes it possible to improve the bonding reliability of the electronic module.

Moreover, a metal layer (for example, Au or the like) provided on the electrode in order to improve the wettability of the solder forms a metal compound at the time of heating, and the molten solder may be repelled at an interface between the electrode and the solder at the time of reflow bonding. The device 200 according to the present disclosure can maintain the wetting and spreading of the solder even in the reflow bonding by having the second layer 302.

The thickness of the second layer 302 may be 100 nm or more. When the thickness of the second layer 302 is 100 nm or more, the above-described effects of maintaining the impact resistance and the wettability in the reflow bonding can be obtained with higher reliability.

The third layer 303 is a layer containing solder. The third layer 303 contains Sn as a main component, and may contain a metal such as Ag or Cu in addition to Sn.

### Configuration of Electronic Module

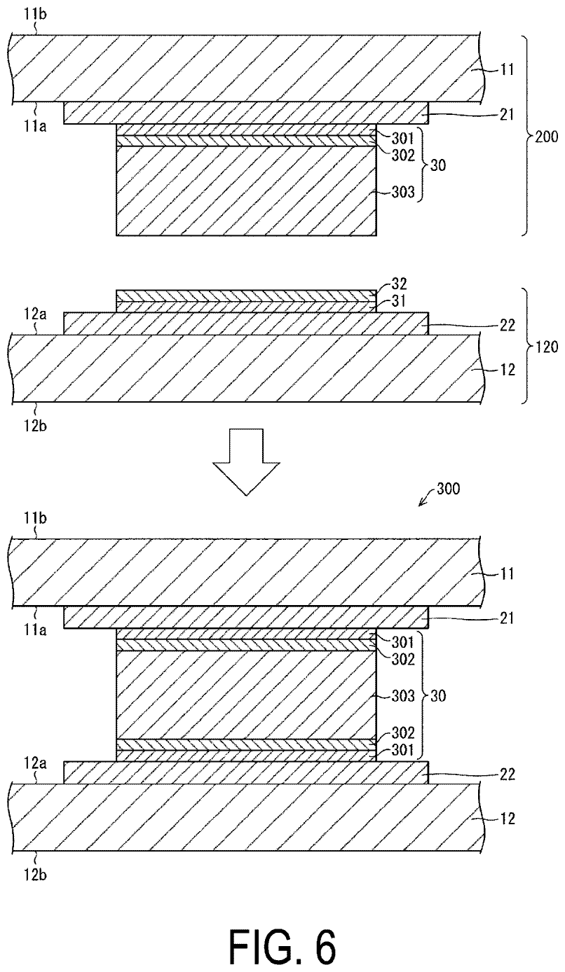

FIG. 6 is a cross-sectional structural view illustrating a part of the electronic module 300 including the device 200. As illustrated in FIG. 6, the electronic module 300 can be configured by mounting the device 200 on a mounting substrate (module substrate) 120. The electronic module 300 is an example of an electrical device according to the present disclosure.

The electronic module 300 can be manufactured by reflow bonding the device 200 and the mounting substrate 120. That is, the electronic module 300 includes the device 200. The mounting substrate 120 is a circuit board mounted on the electronic module 300, and may include an electrical circuit inside and/or outside the mounting substrate 120. The mounting substrate 120 includes a base 12, an electrode 22, a barrier layer 31, and a bonding layer 32 in a state before reflow bonding, similarly to the substrate 110. The electrode 22 of the mounting substrate 120 electrically connects the mounting substrate 120 to an electronic device or the like. The electrode 22 is located on a first surface 12a of the base 12. The base 12, the electrode 22, the barrier layer 31, and the bonding layer 32 of the mounting substrate 120 may have the same configurations as the base 11, the electrode 21, the barrier layer 31, and the bonding layer 32 of the substrate 110, respectively.

More specifically, the electronic module 300 includes the base 11 and the electrode 21 of the device 200, the base 12 and the electrode 22 of the mounting substrate 120, and a bonding portion 30. In other words, the electronic module 300 has a configuration in which the electrode 21 of the device 200 and the electrode 22 of the mounting substrate 120 are bonded by the bonding portion 30. The bonding portion 30 includes a first layer 301, a second layer 302, and a third layer 303 in order from the electrodes 21 and 22. The first layer 301, the second layer 302, and the third layer 303 have the above-described configuration.

The electronic module 300 has the second layer 302, and thus has excellent interfacial strength and can maintain the wetting and spreading of solder even after a high-temperature process such as reflow. This makes it possible to implement an electronic module having excellent bonding reliability and impact resistance.

As described above, the substrate 110 includes the barrier layer 31 and the bonding layer 32, thereby reducing the amount of the compound containing Sn formed in the vicinity of the interface between the solder layer 33 and the bonding layer 32 while securing the wettability of the solder at the time of solder bonding. Thus, the substrate 100 can provide a device or an electronic module having a sufficient interfacial strength in a solder bonding portion even after a high-temperature process such as reflow bonding.

In addition, the device 200 and the electronic module 300 can maintain the wetting and spreading of the solder even after a high-temperature process such as reflow by having the second layer 302. This makes it possible to maintain a sufficient interfacial strength and to implement an electronic module having excellent bonding reliability. Moreover, the properties of the second layer 302 allow an electronic module having excellent impact resistance to be achieved.

### Second Embodiment

Another embodiment of the present disclosure is described below. For convenience of description, members having the same functions as those of the members described in the above-described embodiment are denoted by the same reference signs, and description thereof is not repeated.

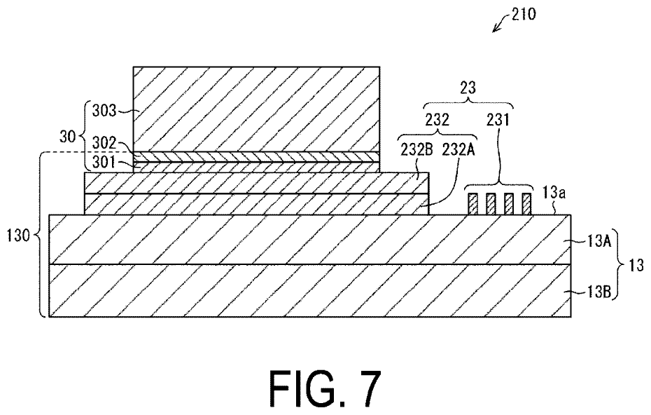

In the second embodiment, an example in which the device 200 is an elastic wave device is described. FIG. 7 is a cross-sectional structural view of an elastic wave device 210 according to the second embodiment.

The elastic wave device 210 includes a base 13, an electrode layer 23, and a bonding portion 30. The elastic wave device 210 can be mounted on a circuit board (mounting substrate) of a communication device.

The base 13 is an example of a base according to the present disclosure. The base 13 includes a piezoelectric layer 13A and a support substrate 13B that supports the piezoelectric layer 13A. The piezoelectric layer 13A has a first surface 13a located on an opposite side of a surface bonded to the support substrate 13B. The electrode layer 23 is provided on the first surface 13a of the piezoelectric layer 13A. The base 13 is not limited to the above configuration. For example, the base 13 may not include the support substrate 13B. In this case, the piezoelectric layer 13A itself also serves as the support substrate 13B.

The electrode layer 23 includes an interdigital transducer (IDT) electrode 231 and a pad portion 232. The pad portion 232 includes a first pad 232A and a second pad 232B. The pad portion 232 in the present embodiment is an example of the electrode 21 according to the present disclosure. The first pad 232A and the second pad 232B are layered in this order from the base 13 side. That is, the pad portion 232 may include a plurality of layers. The first pad 232A may have the same thickness as the IDT electrode 231. The layered structure of the pad portion 232 can reduce electrical resistance.

The elastic wave device 210 is obtained by bonding solder to a substrate 130. The substrate 130 has a barrier layer and a bonding layer according to the present disclosure on the pad portion 232. The substrate 130 is an example of a substrate according to the present disclosure.

By the solder bonding, the barrier layer and the bonding layer form a bonding portion 30 with the solder. The bonding portion 30 is located on the pad portion 232, and includes a first layer 301, a second layer 302, and a third layer 303 in order from the pad portion 232 side. In the elastic wave device 210, the first layer 301, the second layer 302, and the third layer 303 are layered in this order from the pad portion 232 side. The first layer 301, the second layer 302, and the third layer 303 have the same configuration as described in the first embodiment.

The IDT electrode 231 is a comb-shaped electrode that generates an acoustic wave in the acoustic wave device. The IDT electrode 231 includes a pair of electrodes for applying an AC voltage. The IDT electrode 231 is electrically connected to the pad portion 232.

The elastic wave device 210 has a feature that the number of bonding portions bonded via the bonding portion 30 is small as compared with other electronic devices. Therefore, securing the interfacial strength in the bonding portion 30 is more important. Since the elastic wave device 210 includes the substrate 130 and the bonding portion 30, a sufficient interfacial strength can be secured in a solder bonding portion even after a high-temperature process such as reflow bonding. In addition, by having the second layer 302, the wetting and spreading of the solder can be maintained even after a high-temperature process such as reflow. This makes it possible to implement an acoustic wave device having excellent bonding reliability. Moreover, the properties of the second layer 302 allow an acoustic wave device having excellent impact resistance to be achieved.

In the second embodiment, a surface acoustic wave (SAW) has been described as an acoustic wave device; however, the present disclosure is not limited thereto. The acoustic wave device may be, for example, a bulk acoustic wave (BAW).

### Demonstration Test

Demonstration tests for demonstrating the effects of the substrate, the device, and the electrical device of the present disclosure are described below.

### First Demonstration Test: Comparison by Micrograph

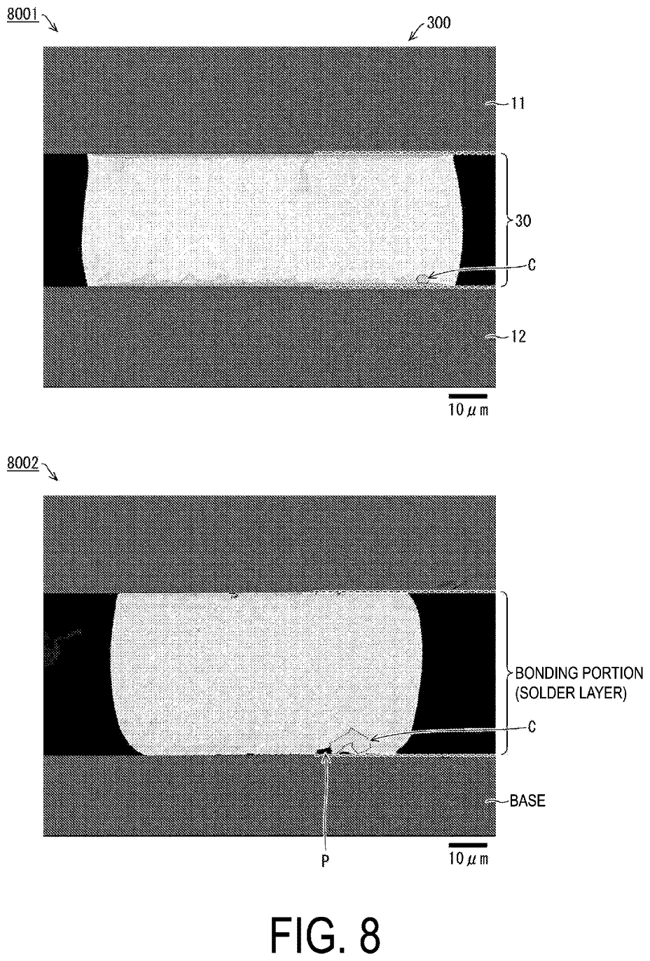

FIG. 8 is a micrograph of the bonding portion 30 of the electronic module. Reference sign 8001 in FIG. 8 denotes a micrograph of the bonding portion 30 of the electronic module 300 according to an example of the present disclosure. Reference sign 8002 in FIG. 8 denotes a micrograph of a bonding portion of an electronic module as a comparative example. In the electronic module of the comparative example, a solder layer is located between an electrode on an electronic device side and a mounting substrate. That is, the electronic module of the comparative example does not include the first layer 301 and the second layer 302 according to the present disclosure. More specifically, the electronic module of the comparative example is obtained by bonding an electronic device and a mounting substrate, which do not have the barrier layer 31 and the bonding layer 32 according to the present disclosure on the electrode, to each other with solder. The heating conditions during the solder bonding are the same in both the example and the comparative example.

In the comparative example denoted by reference sign 8002 in FIG. 8, a region C containing a large amount of compounds formed by a reaction between an electrode metal and a metal contained in a solder layer is present as a coarse granular region in the vicinity of an interface of the bonding portion. In addition, since a large amount of electrode metals are eluted to the solder layer side, a void P is formed at the interface of the bonding portion.

On the other hand, in the electronic module 300 according to the present disclosure denoted by reference sign 8001 in FIG. 8, a region C present near the interface of the bonding portion 30 is relatively small. In addition, the void P observed in the comparative example was not observed.

A device manufactured using a substrate having the barrier layer 31 and the bonding layer 32 according to the present disclosure has a bonding portion including the first layer 301 and the second layer 302. It was demonstrated that the device having the bonding portion including the first layer 301 and the second layer 302 can significantly reduce the formation of brittle compounds in a solder bonding portion even after a high-temperature process such as reflow bonding. In addition, it was also demonstrated that the barrier layer 31 reduces the elution of the electrode metal to the solder layer side, and thus the possibility of the occurrence of a void at the interface between the electrode and the bonding portion can be reduced.

From the above, it was demonstrated that the substrate, the device, and the electrical device according to the present disclosure can secure a sufficient interfacial strength in a solder bonding portion even after a high-temperature process or the like.

### Second Demonstration Test: First Bonding Strength Test-Effect Caused by Difference in Metal Used as Barrier Layer

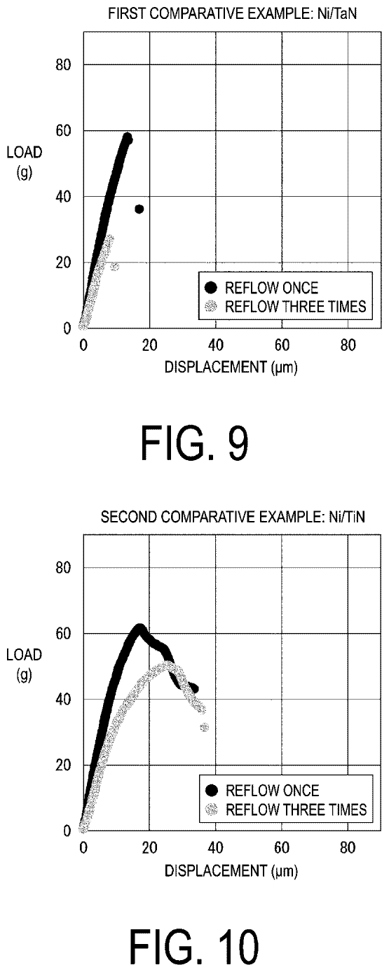

FIGS. 9 to 12 are graphs of the results of evaluating the bonding strength when the metal used for the barrier layer is changed. The evaluation test of the bonding strength was performed in accordance with the standard of solder ball shear of JEDEC JESD22-B117.

In a first comparative example, a Ni layer as an electrode and a TaN (tantalum nitride) layer as a barrier layer were layered on a substrate, and solder balls were placed thereon. FIG. 9 illustrates the results of a test performed after the reflow process was performed once and a test performed after the reflow process was performed three times on the configuration of the first comparative example.

In a second comparative example, a Ni layer as an electrode and a TiN (titanium nitride) layer as a barrier layer were layered on a substrate, and solder balls were placed thereon. FIG. 10 illustrates the results for the second comparative example.

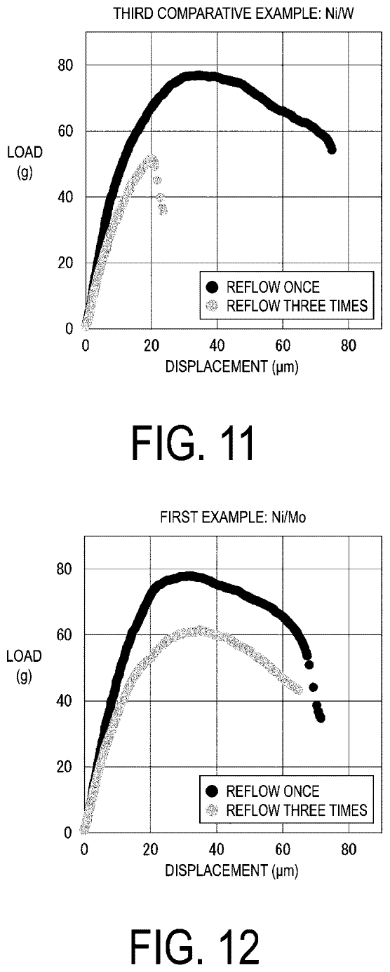

In a third comparative example, a Ni layer as an electrode and a W (tungsten) layer as a barrier layer were layered on a substrate, and solder balls were placed thereon. FIG. 11 illustrates the results for the third comparative example.

In a first example, a Ni layer as an electrode and a Mo (molybdenum) layer as a barrier layer, which is the same as the barrier layer 31 of the present disclosure, were layered on a substrate, and solder balls were placed thereon. FIG. 12 illustrates the results for the example.

In the first comparative example and the second comparative example, the graphs show that the load sharply drops at a relatively small displacement in both cases of one reflow process and three reflow processes. This indicates that the interfacial strength is weak and that peeling occurs at the solder interface at the displacement at which the load sharply drops.

In the third comparative example, in the case of one reflow process, the graph does not show that the load sharply drops within the test range of the displacement. The gentle decrease in the load indicates that bulk solder failure, rather than peeling, has occurred. However, the result of the case where the reflow process is performed three times shows a graph in which the load sharply drops at a small displacement. That is, the third comparative example indicates that the interfacial strength is weakened by the repetition of the reflow process.

On the other hand, in the example, also in both cases of one reflow process and three reflow processes, the graph does not show that the load sharply drops within the test range of the displacement. That is, it was demonstrated that the interfacial strength is maintained within the test range of the displacement.

From the above test results, it was demonstrated that by using the barrier layer 31 containing Mo as a main component, a sufficient interfacial strength can be secured in a solder bonding portion even after a high-temperature process such as reflow bonding.

### Third Demonstration Test: Second Bonding Strength Test-Verification of Configurations of Barrier Layer and Bonding Layer

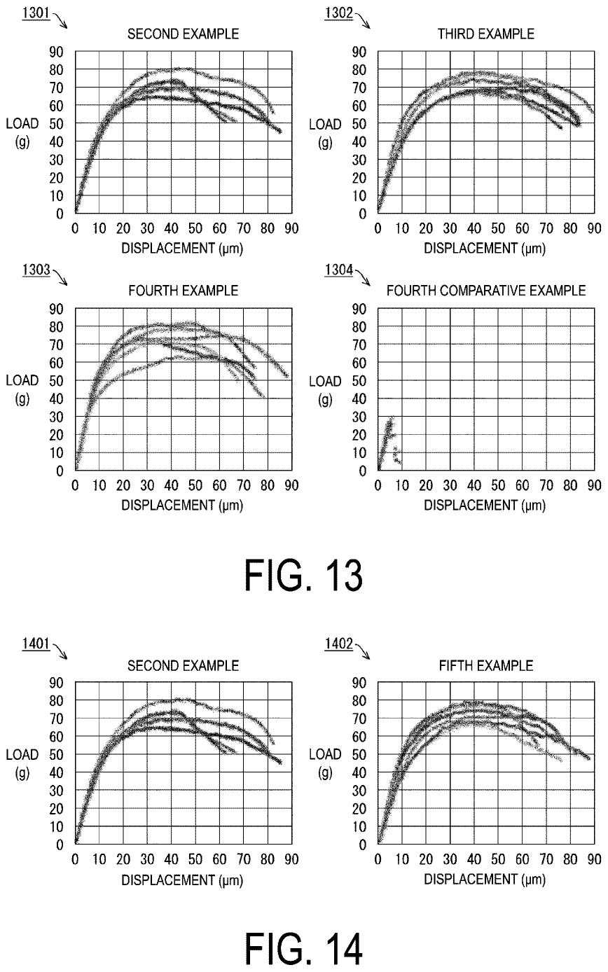

FIG. 13 is a graph of the results of evaluating the bonding strength when the configurations of the barrier layer and the bonding layer are changed using a model sample of the device. The evaluation test of the bonding strength was performed in accordance with the standard of solder ball shear of JEDEC JESD22-B117. The evaluation test of the bonding strength was performed after the reflow process is performed three times on each example and a comparative example. The same test was performed six times on each example and the comparative example.

As samples of devices used in the third demonstration test, second to fourth examples and a fourth comparative example were prepared as follows. In all of the examples and comparative example, a base is common and is a Si substrate. An electrode was also common, and had a layered structure including an Al layer as a wiring layer, a Ti layer as an adhesion layer, and a Ni layer as a protective layer.

Second example: A layered structure of a barrier layer-Mo layer (0.3 μm), a bonding layer-Ni layer (0.2 μm), and an Au layer (0.05 μm). Solder balls are placed on the bonding layer, and the sample is formed.

Third example: A layered structure of a barrier layer-Mo layer (0.1 μm), a bonding layer-Ni layer (0.2 μm), and an Au layer (0.05 μm). Solder balls are placed on the bonding layer, and the sample is formed.

Fourth example: A layered structure of a barrier layer-Mo layer (0.3 μm), a bonding layer-Ni layer (0.1 μm), and an Au layer (0.05 μm). Solder balls are placed on the bonding layer, and the sample is formed.

Fourth comparative example: A layered structure of a bonding layer-Ni layer (0.6 μm) and an Au layer (0.05 μm) with no barrier layer. Solder balls are placed on the bonding layer, and the sample is formed.

Reference sign 1301 in FIG. 13 denotes the result of the second example. Reference sign 1302 in FIG. 13 denotes the result of the third example. Reference sign 1303 in FIG. 13 denotes the result of the fourth example. Reference sign 1304 in FIG. 13 denotes the result of the fourth comparative example.

The second to fourth examples are configurations within the scope of the present disclosure. The fourth comparative example includes no barrier layer containing Mo as a main component, and thus has a configuration out of the scope of the present disclosure.

In the fourth comparative example, the load sharply dropped at a displacement of less than 10 μm. On the other hand, in the second to fourth examples, it was demonstrated that the load does not sharply drop within the test range of the displacement and the interfacial strength is maintained within the test range of the displacement.

From the result of the third example, it was demonstrated that the barrier layer according to the present disclosure has a thickness of 0.1 μm or more and thus a sufficient interfacial strength can be secured in a solder bonding portion even after a high-temperature process such as reflow bonding. In addition, from the result of the fourth example, it was demonstrated that the bonding layer according to the present disclosure has a thickness of 0.05 μm or more and thus a sufficient interfacial strength can be secured in a solder bonding portion even after a high-temperature process such as reflow bonding.

### Fourth Demonstration Test: Third Bonding Strength Test-Verification of Bonding Strength by Presence or Absence of Protective Layer

FIG. 14 is a graph of the results of evaluating the bonding strength in the electrode according to the present disclosure in the case where the electrode has a protective layer and in the case where the electrode has no protective layer. The evaluation test of the bonding strength was performed in accordance with the standard of solder ball shear of JEDEC JESD22-B117.

Reference sign 1401 in FIG. 14 denotes the result of the third demonstration test using the sample of the second example. In the second example, the electrode has a layered structure including an Al layer as a wiring layer, a Ti layer as an adhesion layer, and a Ni layer as a protective layer.

Reference sign 1402 in FIG. 14 denotes the result of a fifth example in which the electrode has a layered structure including an Al layer as a wiring layer and a Ti layer as an adhesion layer. That is, the fifth example has no Ni layer as a protective layer, and has a configuration in which the adhesion layer and the barrier layer are in contact with each other. The fifth example is a configuration within the scope of the present disclosure.

Also in the fifth example, it was demonstrated that the load does not sharply drop within the test range of the displacement and the interfacial strength is maintained within the test range of the displacement.

That is, it was demonstrated that in the substrate according to the present disclosure, when the adhesion layer and the barrier layer are in contact with each other, a sufficient interfacial strength can be secured in a solder bonding portion even after a high-temperature process such as reflow bonding.

### Fifth Demonstration Test: Fourth Bonding Strength Test-High-temperature Test

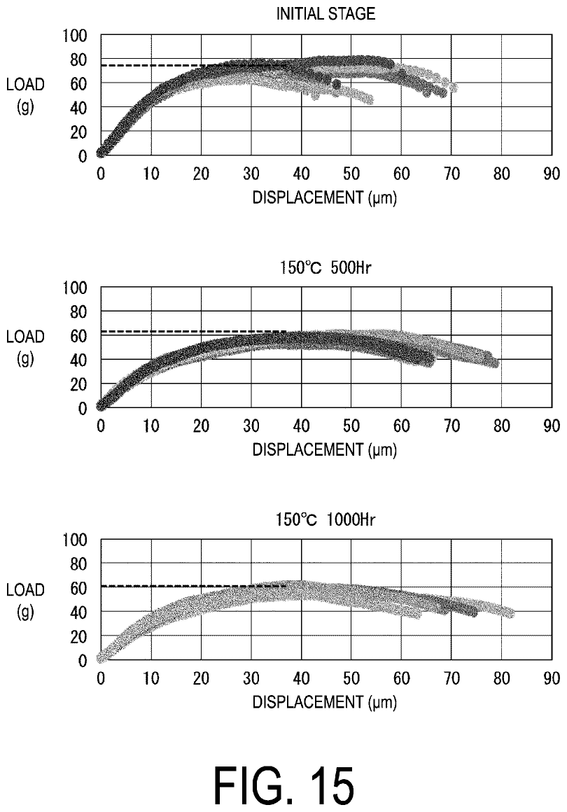

A high-temperature test was performed using a sample having the bonding portion according to the present disclosure, and observation of a cross-sectional structure and evaluation of bonding strength after the high-temperature test were performed. FIG. 15 illustrates the results of the evaluation test of the bonding strength. The high-temperature test was performed under conditions of 150 °C and 1000 hours in accordance with the standard of IEC 60068-2-2. The evaluation test of the bonding strength was performed in accordance with the standard of solder ball shear of JEDEC JESD22-B117.

The samples used for observing the cross-sectional structure in the fifth demonstration test were obtained by placing solder balls on the following substrate sample and then reflow bonding the substrate sample to the following mother substrate sample.

Substrate sample: A layered structure of a base-Si substrate, an electrode-Ni layer (0.6 μm), and a Ti layer (0.05 μm), a layered structure of a barrier layer-Mo layer (0.3 μm), a bonding layer-Ni layer (0.2 μm), and an Au layer (0.05 μm) Mother substrate sample: A layered structure of a base-Si substrate, an electrode-Ni layer (0.6 μm), and a Ti layer (0.05 μm), a layered structure of a barrier layer-Mo layer (0.3 μm), a bonding layer-Ni layer (0.2 μm), and an Au layer (0.05 μm).

The samples produced as described above are within the scope of the present disclosure and have an electrode and a bonding portion located on the electrode. The bonding portion includes a first layer containing Mo as a main component, a second layer containing β-Sn as a main component, and a third layer containing solder in order from the electrode side.

The samples used for evaluating the bonding strength in the fifth demonstration test were produced by placing solder balls on the above substrate sample. As illustrated in FIG. 15, the samples within the scope of the present disclosure were demonstrated that the load does not sharply drop within the test range of the displacement and the interfacial strength is maintained within the test range of the displacement.

That is, it was demonstrated that the substrate according to the present disclosure can secure a sufficient interfacial strength in the high-temperature test performed under conditions of 150 °C and 1000 hours.

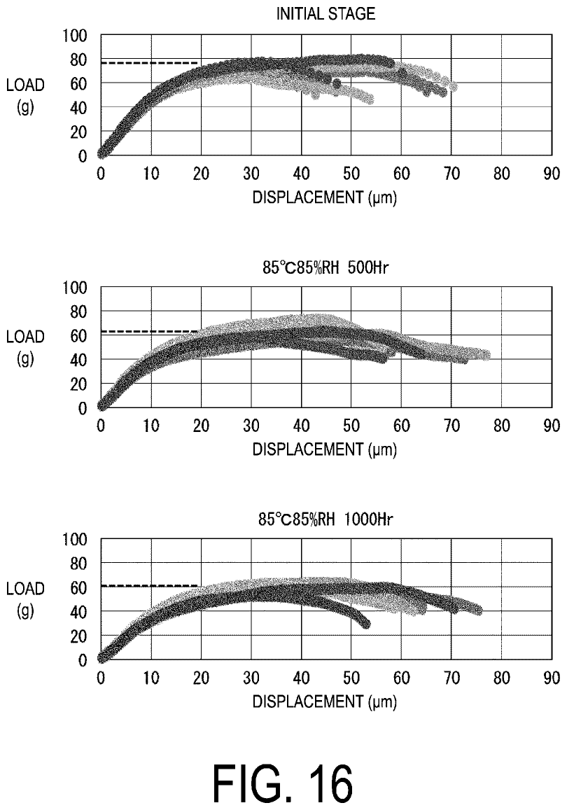

Sixth demonstration Test: Fifth Bonding Strength Test-High-temperature and High-Humidity Test
A high-temperature and high-humidity test was performed using a sample having the bonding portion according to the present disclosure, and observation of a cross-sectional structure and evaluation of bonding strength after the high-temperature and high-humidity test were performed. FIG. 16 illustrates the results of the evaluation test of the bonding strength. The high-temperature and high-humidity test was performed under conditions of 85 °C, 85 RH, and 1000 hours in accordance with the standard of IEC60068-2-78. The evaluation test of the bonding strength was performed in accordance with the standard of solder ball shear of JEDEC JESD22-B117.

The samples used for observing the cross-sectional structure in the sixth demonstration test were obtained by placing solder balls on the following substrate sample and then reflow bonding the substrate sample to the following mother substrate sample.

Substrate sample: A layered structure of a base-Si substrate, an electrode-Ni layer (0.6 μm), and a Ti layer (0.05 μm), a layered structure of a barrier layer-Mo layer (0.3 μm), a bonding layer-Ni layer (0.2 μm), and an Au layer (0.05 μm) Mother substrate sample: A layered structure of a base-Si substrate, an electrode-Ni layer (0.6 μm), and a Ti layer (0.05 μm), a layered structure of a barrier layer-Mo layer (0.3 μm), a bonding layer-Ni layer (0.2 μm), and an Au layer (0.05 μm).

The samples produced as described above are within the scope of the present disclosure and have an electrode and a bonding portion located on the electrode. The bonding portion includes a first layer containing Mo as a main component, a second layer containing β-Sn as a main component, and a third layer containing solder in order from the electrode side.

The samples used for evaluating the bonding strength in the sixth demonstration test were produced by placing solder balls on the above substrate sample. As illustrated in FIG. 16, the samples within the scope of the present disclosure were demonstrated that the load does not sharply drop within the test range of the displacement and the interfacial strength is maintained within the test range of the displacement.

That is, it was demonstrated that the electronic module according to the present disclosure can secure a sufficient interfacial strength in the high-temperature and high-humidity test for 1000 hours under the conditions of 85 °C and 85% RH.

### Seventh Demonstration Test: First Temperature Cycle Test

A temperature cycle test was performed using a model sample of an electronic module having the bonding portion according to the present disclosure, and cross sections of a sample of an example (sixth example) and a sample of a comparative example (fifth comparative example) after the temperature cycle test were observed.

The temperature cycle test was performed in accordance with the standard of IEC 60068-2-14, with 300 cycles of repeated temperature changes from −40 °C to 85 °C. The observation of the cross section was performed by extracting the sample every 50 cycles and using an SEM photograph of each sample embedded in resin and polished.

The sample of the example (sixth example) and the sample of the comparative example (fifth comparative example) used in the seventh demonstration test were obtained by placing solder balls on the following substrate samples and then reflow-bonding the substrate samples to the following mother substrate samples.

Sixth example: substrate sample: A layered structure of a base-Si substrate, an electrode-Ni layer (0.6 μm), and a Ti layer (0.05 μm), a layered structure of a barrier layer-Mo layer (0.3 μm), a bonding layer-Ni layer (0.2 μm), and an Au layer (0.05 μm) Mother substrate sample: A layered structure of a base-LiTaO₃ substrate, an electrode-Ni layer (0.6 μm), and a Ti layer (0.05 μm), a layered structure of a barrier layer-Mo layer (0.3 μm), a bonding layer-Ni layer (0.2 μm), and an Au layer (0.05 μm).

The sixth example produced as described above is within the scope of the present disclosure and has an electrode and a bonding portion located on the electrode. The bonding portion includes a first layer containing Mo as a main component, a second layer containing β-Sn as a main component, and a third layer containing solder in order from the electrode side.

Fifth comparative example: substrate sample: A layered structure of a base-Si substrate, an electrode-Ni layer (0.6 μm), and a Ti layer (0.05 μm), a layered structure of a bonding layer-Ni layer (0.6 μm) and an Au layer (0.05 μm) with no barrier layer Mother substrate sample: A layered structure of a base-LiTaO₃ substrate, an electrode-Ni layer (0.6 μm), and a Ti layer (0.05 μm), a layered structure of a bonding layer-Ni layer (1.2 μm) and an Au layer (0.05 μm) with no barrier layer.

The electronic module of the fifth comparative example produced as described above does not include the first layer and the second layer according to the present disclosure, and is out of the scope of the present disclosure.

According to the seventh demonstration test, in the comparative example, substrate cracking was observed in 50 cycles or more. On the other hand, in the sixth example, although fatigue was observed in the bonding portion at 200 cycles or more, no substrate cracking was observed even at 300 cycles. This result is considered to be a result of the fact that the difference in thermal expansion can be absorbed in the bonding portion by forming the bonding portion to be flexible.

That is, it was demonstrated that the electronic module according to the present disclosure obtains sufficient bonding reliability in the temperature cycle test of 300 cycles from 40 °C to 85 °C.

### Eighth Demonstration Test: Hardness of Bonding Portion

In the eighth demonstration test, the hardness of solder (bonding portion) in a device within the scope of the present disclosure and the hardness of solder in a device out of the scope of the present disclosure were evaluated by nanoindentation.

A sample of an example (seventh example) and a sample of a comparative example (sixth comparative example) used in the eighth demonstration test were prepared as follows.

Seventh example: A layered structure of a base-Si substrate, an electrode-Ni layer (0.6 μm), and a Ti layer (0.05 μm), a layered structure of a barrier layer-Mo layer (0.3 μm), a bonding layer-Ni layer (0.2 μm), and an Au layer (0.05 μm). Two substrates having the above structure were prepared and bonded to each other with solder.

The sample of the seventh example produced as described above is within the scope of the present disclosure, and the bonding portion according to the present disclosure is formed on the electrode. The bonding portion includes a first layer containing Mo as a main component, a second layer containing β-Sn as a main component, and a third layer containing solder in order from the electrode side.

Fifth comparative example: A layered structure of a base-Si substrate, an electrode-Ni layer (0.6 μm), and a Ti layer (0.05 μm), a layered structure of a bonding layer-Ni layer (1.2 μm) and an Au layer (0.05 μm) with no barrier layer. Two substrates having the above structure were prepared and bonded to each other with solder.

The device of the fifth comparative example produced as described above does not have the first layer and the second layer according to the present disclosure, and is out of the scope of the present disclosure.

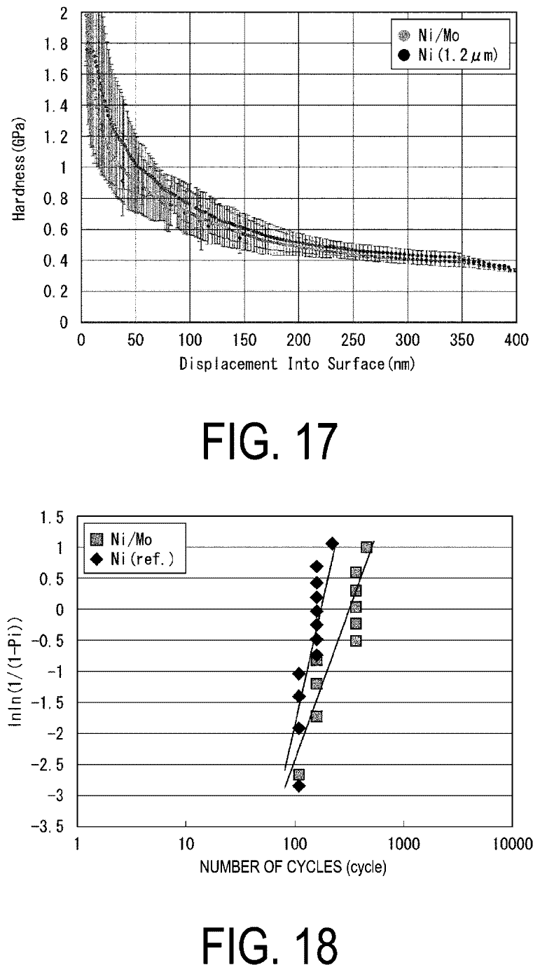

FIG. 17 is a graph showing the results of nanoindentation of the seventh example (Ni/Mo) and the sixth comparative example (Ni (1.2 μm)). As can be seen from FIG. 17, the hardness of the solder is lower in the seventh example. That is, it was demonstrated that the bonding portion according to the present disclosure has a lower height than the bonding portion not including the first layer and the second layer as in the sixth comparative example and can absorb a difference in thermal expansion due to deformation or the like.

### Ninth Demonstration Test: Second Temperature Cycle Test

A temperature cycle test was performed using a model sample of an electronic module, and Weibull plots were produced for a sample of an example and a sample of a comparative example. The sample of the example and the sample of the comparative example are the same as those of the sixth example and the fifth comparative example produced in the seventh demonstration test. The temperature cycle test was performed in accordance with the standard of IEC 60068-2-14, with 1000 cycles of repeated temperature changes from −55 °C to 125 °C.

FIG. 18 is a Weibull plot of the sixth example (Ni/Mo) and the fifth comparative example (Ni (1.2 μm)). As can be seen from FIG. 18, it was demonstrated that the number of cycles until breakage is longer in the sixth example. That is, it was demonstrated that the electronic module according to the present disclosure has higher bonding reliability than the comparative example.

### Tenth Demonstration Test: Drop Impact Test

A drop impact test was performed using a model sample of an electronic module, and samples of examples and samples of comparative examples were compared. In the drop impact test, in accordance with the standard of JEITA ET-7409/107, an iron ball of 4.1 g was dropped from the drop height of 0.5 m and 1.0 m, and the cross-section of a solder bonding portion was observed to observe a breakage state. The cross section was observed using a SEM photograph.

As model samples of the electronic module used in the tenth demonstration test, eighth and ninth examples and seventh and eighth comparative examples were prepared as follows. In each of the examples and the comparative examples, solder balls were placed on each substrate sample, and then the substrate sample was reflow-bonded to each mother substrate sample. Six samples were prepared and tested for each example and each comparative example.

### Eighth Example:

Substrate sample: A layered structure of a base-Si substrate, an electrode-Ti layer (0.015 μm), and a Ni layer (0.3 μm), a layered structure of a barrier layer-Mo layer (0.3 μm), a bonding layer-Ni layer (0.1 μm), and an Au layer (0.05 μm) Mother substrate sample: A layered structure of a base-Si substrate, an electrode-Ti layer (0.015 μm), and an Ni layer (0.3 μm), a layered structure of a barrier layer-Mo layer (0.3 μm), a bonding layer-Ni layer (0.1 μm), and an Au layer (0.05 μm).

### Ninth Example:

Substrate sample: A layered structure of a base-Si substrate, an electrode-Ti layer (0.015 μm), a barrier layer-Mo layer (0.3 μm), a bonding layer-Ni layer (0.2 μm), and an Au layer (0.05 μm) Mother substrate sample: A layered structure of a base-Si substrate, an electrode-Ti layer (0.015 μm), a barrier layer-Mo layer (0.3 μm), a bonding layer-Ni layer (0.2 μm), and an Au layer (0.05 μm).

### Eighth Comparative Example:

Substrate sample: A layered structure of a base-Si substrate, an electrode-Ti layer (0.050 μm), a bonding layer-Ni layer (1.2 μm), and an Au layer (0.05 μm) Mother substrate sample: A layered structure of a base-Si substrate, an electrode-Ti layer (0.050 μm), a bonding layer-Ni layer (1.2 μm), and an Au layer (0.05 μm).

### Ninth Comparative Example:

Substrate sample: A layered structure of a base-Si substrate, an electrode-Ti layer (0.050 μm), a bonding layer-Ni layer (0.6 μm), and an APC layer (0.1 μm) Mother substrate sample: A layered structure of a base-Si substrate, an electrode-Ti layer (0.050 μm), a bonding layer-Ni layer (0.6 μm), and an APC layer (0.1 μm).

When the drop distance is 0.5 m, no breakage was observed in four of the six samples even after more than 100 drops in the eighth and ninth examples. On the other hand, the breakage was observed when the number of drops was 6.7 times on average in the eighth comparative example, and 7.1 times on average in the ninth comparative example.

That is, it was demonstrated that the electronic module according to the present disclosure has better impact resistance than the comparative examples.

In order to examine the above experimental results in more detail, the following additional experiments were carried out.

### Production of Multilayer Electrode

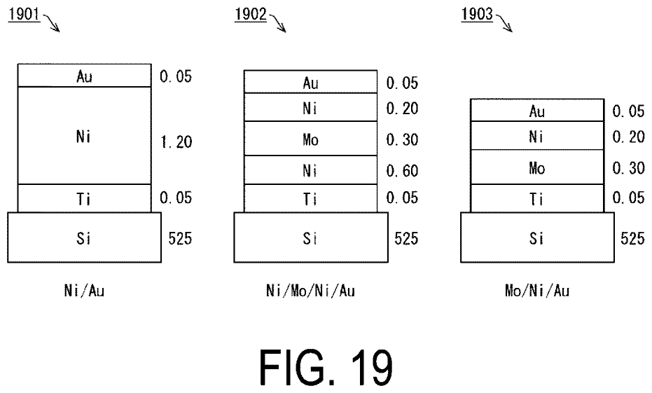

An electrode pattern was formed on a 4-inch Si wafer having a thickness of 525 μm by using a photolithography process, and a film was formed on a Ti seed layer (0.05 μm) by sputtering in a different configuration. The Si wafer is an example of the substrate according to the present disclosure. FIG. 19 is a schematic view of the produced electrode structure. Reference sign 1901 in FIG. 19 denotes a general-purpose Ni/Au electrode as a comparative example. In order to avoid the loss of Ni due to dissolution, the thickness of Ni was set to 1.2 μm. Reference sign 1902 in FIG. 19 denotes a Ni/Mo/Ni/Au electrode as an example of the present disclosure, and a Mo barrier layer was formed on Ni having a thickness of 0.6 μm. The Mo barrier layer is an example of the barrier layer according to the present disclosure. Reference sign 1903 in FIG. 19 denotes an electrode in which Mo/Ni/Au is directly formed on the Ti seed layer as an example of the present disclosure. The Mo layer shown in the example of reference sign 1903 is also an example of the barrier layer according to the present disclosure.

On chips diced into 1.5 mm×1.5 mm and 2.5 mm×1.5 mm, Sn-3.0 mass % Ag-0.5 mass % Cu solder balls having a diameter of 90 μm were mounted. Subsequently, the chips were melted in a formic acid reducing atmosphere with a profile of a peak temperature of 260 °C, and a simple bonded sample in which upper and lower chips were bonded with four electrodes having a diameter of 100 μm was produced. In order to simulate the thermal history during assembly, the reflow was repeated three times.

### Evaluation of Impact Resistance

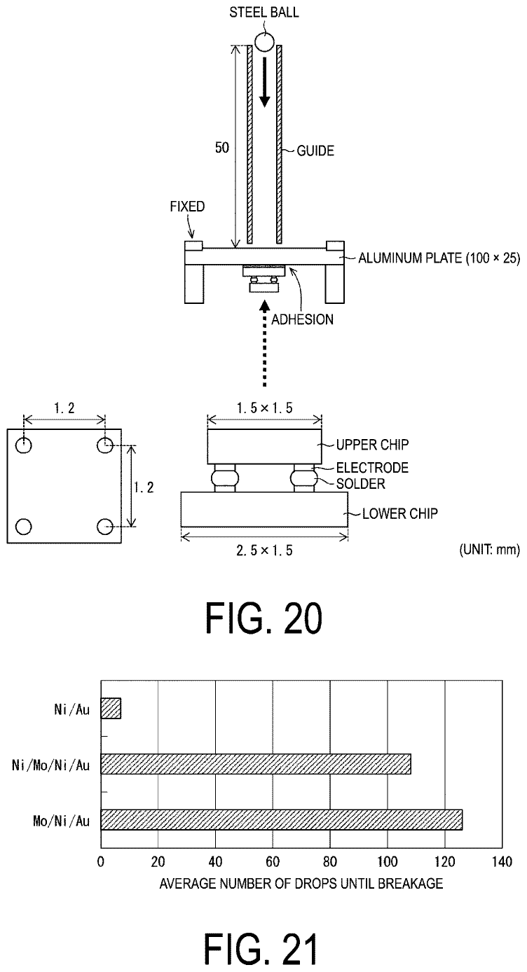

A shear tester is often used for evaluating the strength of the electrode portion, but when the electrode portion has a certain strength or more and breaks inside the solder, the electrode portion is not subjected to the breakage evaluation, making it difficult to determine the superiority or inferiority. Therefore, in this experiment, a steel ball drop test was repeated. FIG. 20 is a diagram illustrating an overview of the steel ball drop test. As illustrated in FIG. 20, both ends of an aluminum plate to which the bonded sample was attached with a cyanoacrylate-based adhesive was fixed, a steel ball with a diameter of 10 mm and a mass of 4.1 g was dropped from a height of 500 mm onto the center of a back surface of the sample, and the number of times the steel ball was dropped onto the upper chip was compared. The number of samples was 5 for each.

### Results and Discussion

FIG. 21 is a graph showing the results of the steel ball drop test. FIG. 21 illustrates the results of comparing the number of steel ball drops until the steel ball is dropped onto the upper chip, between the electrode structures. The Ni/Au electrode of the comparative example was broken after 7 drops on average. On the other hand, the Ni/Mo/Ni/Au electrode and the Mo/Ni/Au electrode, which are examples of the present disclosure and include the Mo barrier layer, had a significantly increased number of repeated drops until breakage, exceeding 100 times. In the general-purpose bump shear test, the electrode portion was broken inside the solder in all cases, but in the steel ball drop test, a clear difference appeared.

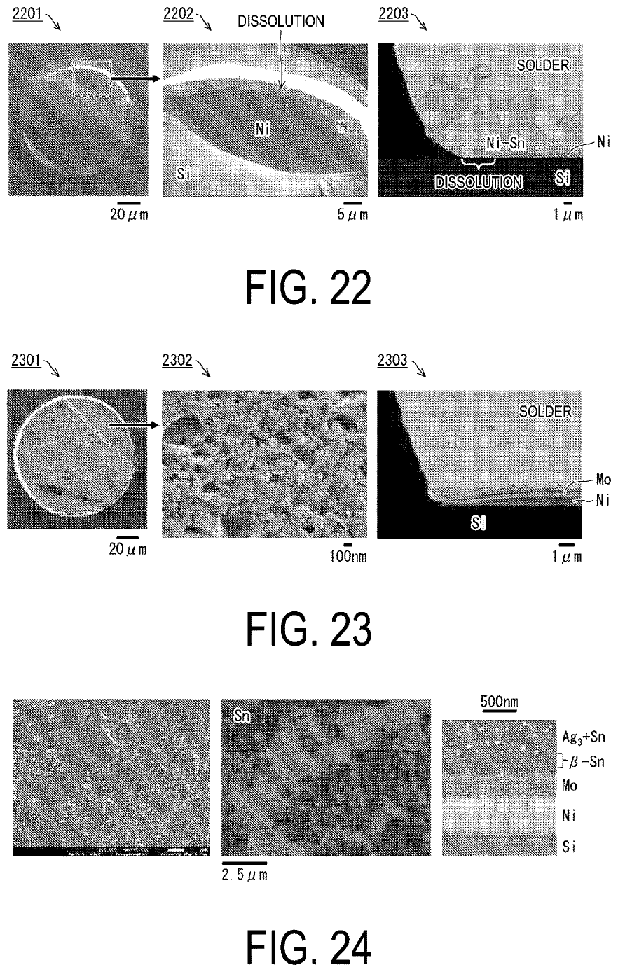

In order to clarify the cause of the difference between the electrodes having different configurations, scanning electron microscope (SEM) observation was performed. FIG. 22 illustrates the SEM observation result of the Ni/Au electrode as the comparative example after the drop test (the number of drops is 5). As denoted by reference signs 2201 and 2202 in FIG. 22, in the electrode, Ni is dissolved and disappears in a width of about 5 μm from the outer peripheral portion of the electrode which is considered to be a breakage starting point. It is presumed that a crack generated with the Ni disappearance portion as an initial defect propagates through an Si interface and leads to the breakage of the Si chip. The dissolution and disappearance of the Ni electrode occur because the electrode thickness of the outer peripheral portion after film formation is thin, but avoiding the dissolution and disappearance is difficult in terms of the process because the dissolution and disappearance are caused by the shadow of resist during sputtering.

On the other hand, FIG. 23 illustrates the SEM observation result of the Ni/Mo/Ni/Au electrode as the example of the present disclosure after the drop test (the number of drops is 289). A striation denoted by reference sign 2302 in FIG. 23 was observed from the outer peripheral portion of the breakage surface of a solder bump denoted by reference sign 2301 in FIG. 23 to a region indicated by a broken line. The striation interval was about 50 nm, and the maximum distance from the outer peripheral portion to the broken line was 20 μm. From the above, it is considered that the fatigue crack has developed to the broken line portion by the repeated dropping of the steel ball and has reached macroscopic breakage, and there is no contradiction. Reference sign 2303 in FIG. 23 denotes a cross-sectional photograph of the electrode portion. It can be seen that Mo covers the thin portion of the Ni layer in the outer peripheral portion and the dissolution of Ni is suppressed. It is considered that the fact that Ni did not disappear and initial defects did not occur in the electrodes of the examples led to a significant increase in the number of drops until breakage. It can be said that the suppression of electrode dissolution by the introduction of the Mo barrier layer is also effective for the improvement of impact resistance.

FIG. 24 illustrates the results of energy dispersive X-ray analysis (EDX) of the breakage surface of the Ni/Mo/Ni/Au electrode as the example of the present disclosure on the Mo layer side. From the observation of the internal structure in the previous study, it can be seen that the structure after the fusion bonding is a Mo/β-Sn/solder layer structure. In the EDX mapping, the Sn layer was widely distributed on the Mo layer, but the amount of Ag detected was very small. The layer remaining on the Mo layer was mainly the-Sn layer, suggesting that the crack developed at the interface between the solder and the β-Sn.

The mode of breakage of the Mo/Ni/Au electrode as the example of the present disclosure was similar to that of the Ni/Mo/Ni/Au electrode. Removing the Ni layer is expected to further reduce the electrode thickness and shorten the film formation time, thereby increasing the productivity.

From the above, it can be seen that, in the Ni/Au electrode as the comparative example, the electrode dissolution portion of about 5 μm in the outer peripheral portion having a small thickness becomes an initial defect and leads to chip breakage, but the impact resistance is improved by suppressing the dissolution by the Mo barrier layer. The breakage of the electrode structure including the Mo barrier layer after solder bonding is mainly ductile breakage occurring at the β-Sn/solder interface.

### Conclusion

(1) A device according to a first aspect of the present disclosure comprises: a base comprising a first surface; an electrode located on the first surface of the base; and a bonding portion located on the electrode, wherein the bonding portion comprises a first layer, a second layer, and a third layer in order from a side of the electrode, the first layer comprises Mo as a main component, the second layer comprises β-Sn as a main component, and the third layer comprises solder.
(2) In the device according to a second aspect of the present disclosure, in the first aspect, the electrode comprises a wiring layer configured to communicate signals and an adhesion layer configured to increase adhesion between the wiring layer and the first layer, and the adhesion layer and the first layer are in contact with each other.
(3) In the device according to a third aspect of the present disclosure, in the second aspect, the adhesion layer comprises at least one of a layer comprising Ti as a main component and a layer comprising Cr as a main component.
(4) In the device according to a fourth aspect of the present disclosure, in any one of the first to third aspects, the second layer has a thickness of 100 nm or more.
(5) In the device according to a fifth aspect of the present disclosure, in any one of the first to fourth aspects, a {111} plane of Mo that the first layer comprises and a {110} plane of β-Sn that the second layer comprises are substantially parallel to each other.
(6) In the device according to a sixth aspect of the present disclosure, in any one of the first to fifth aspects, the base comprises a piezoelectric layer, and the electrode is provided on the piezoelectric layer and is connected to an IDT electrode.
(7) An electrical device according to a seventh aspect of the present disclosure comprises the device of any one of the first to sixth aspects.
(8) A substrate according to an eighth aspect of the present disclosure comprises: a base comprising a first surface; an electrode located on the first surface of the base; a barrier layer located on the electrode; and a bonding layer located on the barrier layer, wherein the barrier layer comprises Mo as a main component, and the bonding layer comprises at least one of Ni, Ag, Au, and Cu.
(9) In the substrate according to a ninth aspect of the present disclosure, in the eighth aspect, the bonding layer comprises a layer made of a silver alloy comprising Ag as a main component.
(10) A method for manufacturing a device according to a tenth aspect of the present disclosure comprises: preparing the substrate of the eighth or ninth aspect, and placing solder on the bonding layer and heating the solder to produce a bonding portion on the electrode, wherein the bonding portion comprises a first layer, a second layer, and a third layer in order from a side of the electrode, the first layer comprises Mo as a main component, the second layer comprises β-Sn as a main component, and the third layer comprises solder.

### Supplementary Note

The invention according to the present disclosure has been described above based on various drawings and examples. However, the invention according to the present disclosure is not limited to each embodiment described above. That is, the embodiments of the invention according to the present disclosure can be varied in various ways within the scope illustrated in the present disclosure, and embodiments obtained by appropriately combining the technical means disclosed in different embodiments are also included in the technical scope of the invention according to the present disclosure. In other words, a person skilled in the art can easily make various variations or corrections based on the present disclosure. Note that these variations or corrections are included within the scope of the present disclosure.

### REFERENCE SIGNS

110 Substrate
11 Base
21 Electrode
21A Wiring layer
21B Adhesion layer
31 barrier layer
32 Bonding layer
120 Mounting substrate
12 Base
22 Electrode
200 Device
30 Bonding portion
301 First layer
302 Second layer
303 Third layer
300 Electronic module (electrical device)
210 Elastic wave device (device)
130 Substrate
13 Base
13A Piezoelectric layer (base)
13B Support substrate (base)
23 Electrode layer
231 IDT electrode
232 Pad portion (electrode)

1. A device comprising:
a base comprising a first surface;
an electrode located on the first surface of the base; and
a bonding portion located on the electrode,
wherein the bonding portion comprises a first layer, a second layer, and a third layer in order from a side of the electrode,
the first layer comprises Mo as a main component,
the second layer comprises β-Sn as a main component, and
third layer comprises solder.

2. The device according to claim 1, wherein the electrode comprises a wiring layer configured to communicate signals and an adhesion layer configured to increase adhesion between the wiring layer and the first layer, and
the adhesion layer and the first layer are in contact with each other.

3. The device according to claim 2, wherein the adhesion layer comprises at least one of a layer comprising Ti as a main component and a layer comprising Cr as a main component.

4. The device according to claim 1, wherein the second layer has a thickness of 100 nm or more.

5. The device according to claim 1, wherein a {111} plane of Mo that the first layer comprises and a {110} plane of β-Sn that the second layer comprises are substantially parallel to each other.

6. The device according to any one of claim 1, wherein the base comprises a piezoelectric layer, and
the electrode is provided on the piezoelectric layer and is connected to an IDT electrode.

7. An electrical device comprising the device according to claim 1.

8. A substrate comprising:
a base comprising a first surface;
an electrode located on the first surface of the base;
a barrier layer located on the electrode; and
a bonding layer located on the barrier layer,
wherein the barrier layer comprises Mo as a main component, and the bonding layer comprises at least one of Ni, Ag, Au, and Cu.

9. The substrate according to claim 8, wherein the bonding layer comprises a layer made of a silver alloy comprising Ag as a main component.

10. A method for manufacturing a device, the method comprising:
preparing the substrate according to claim and
placing solder on the bonding layer and heating the solder to produce a bonding portion on the electrode,
wherein the bonding portion comprises a first layer, a second layer, and a third layer in order from a side of the electrode,
the first layer comprises Mo as a main component,
the second layer comprises β-Sn as a main component, and
the third layer comprises solder.
